(19) United States
(12) Patent Application Publication
(10) Pub. No.: US 2012/0100707 A1
(43) Pub. Date: Apr. 26, 2012

(54) METHOD FOR FABRICATING NON-VOLATILE MEMORY DEVICE WITH THREE-DIMENSIONAL STRUCTURE

(76) Inventor: Choon-Kun RYU, Gyeonggi-do (KR)

(21) Appl. No.: 13/280,799

(22) Filed: Oct. 25, 2011

(30) Foreign Application Priority Data
Oct. 26, 2010 (KR) 10-2010-0104802

(51) Int. Cl. H01L 21/28

(52) U.S. Cl. 438/593; 257/E21.209

(57) ABSTRACT

A method for fabricating a non-volatile memory device with a three-dimensional structure includes forming a pipe gate conductive layer on a substrate, forming a pipe channel hole in the pipe gate conductive layer, burying a first sacrificial layer in the pipe channel hole, stacking interlayer dielectric layers and gate conductive layers on the pipe gate conductive layer including the first sacrificial layer, forming a pair of cell channel holes in the interlayer dielectric layers and the gate conductive layers, forming a second sacrificial layer on a resultant structure including the pair of cell channel holes, and forming a third sacrificial layer with etching selectivity relative to the second sacrificial layer on the second sacrificial layer and filling the cell channel holes with the third sacrificial layer.

### CROSS-REFERENCE TO RELATED APPLICATIONS

The present application claims priority of Korean Patent Application No. 10-2010-0104802, filed on Oct. 26, 2010, which is incorporated herein by reference in its entirety.

### BACKGROUND

1. Field

Exemplary embodiments of the present invention relate to a method for fabricating a non-volatile memory device, and more particularly, to a method for fabricating a non-volatile memory device with a three-dimensional structure.

2. Description of the Related Art

A non-volatile memory device refers to a memory device that retains stored data although power is off.

To further increase the degree of integration in a memory device, a memory device may have a three-dimensional structure, which vertically stacks memory cells from a substrate. In a three-dimensional structure, strings may be vertically arranged from a substrate to increase the degree of integration for a memory device. The non-volatile memory device with a three-dimensional structure as described above includes memory cells having vertical channels. When stacking the memory cells in the vertical direction, a sacrificial layer is formed in channel holes, and the sacrificial layer is removed in a subsequent process. Hereafter, features of the conventional art will be described with reference to the drawings.

FIGS. 1A and 1B are cross-sectional views illustrating a process for forming a sacrificial layer in channel holes of a non-volatile memory device with a three-dimensional structure and a process for removing the sacrificial layer.

Referring to FIG. 1A, an insulation layer 11 is formed on a substrate 10, and a conductive layer 12 for forming a pipe gate is formed on the insulation layer 11. The insulation layer may include an oxide layer, and the conductive layer 12 may include polysilicon.

The conductive layer 12 is etched to form pipe channel holes. The pipe channel holes are spaces where a pipe channel for connecting a pair of cell channel holes to each other is to be formed.

A nitride layer is filled in the pipe channel holes as a sacrificial layer. By forming the sacrificial layer in the pipe channel holes, the conductive layer 12 has a pipe channel sacrificial layer 13 buried within.

Interlayer dielectric layers 14 and gate conductive layers 15 are alternately stacked on a resultant structure including the conductive layer 12 and the pipe channel sacrificial layer 13. The gate conductive layers 15 may include polysilicon, and the interlayer dielectric layers 14 may include an oxide layer. The gate conductive layers 15 correspond to gate electrodes of memory cells, and each gate conductive layer 15 constitutes a word line.

The interlayer dielectric layers 14 and the gate conductive layers 15 are etched to form a pair of cell channel holes that expose the pipe channel sacrificial layer 13. A charge blocking layer, a charge trap layer/a charge storage layer, and a tunnel insulation layer are sequentially formed on sidewalls of the cell channel holes. A channel layer is also filled in the cell channel holes, so that channels of memory cells may be formed later.

A cell channel sacrificial layer 16 is filled in the cell channel holes. The cell channel sacrificial layer 16 includes a material with etching selectivity relative to the interlayer dielectric layer 14 and the gate conductive layer 15. The cell channel sacrificial layer 16 may be formed of a nitride layer because the interlayer dielectric layers 14 and the gate conductive layers 15 are formed of an oxide layer and a polysilicon layer, respectively.

Referring to FIG. 1B, a trench process is performed. In the trench process, the gate conductive layers 15 formed between the cell channel holes are separated from each other by etching a trench between the cell channel holes. By forming the trench, word lines are separated from each other according to cell channels.

In the trench process, the interlayer dielectric layers 14 and the gate conductive layers 15 formed between the pair of cell channel holes are etched, thereby forming the trench. An insulation layer 19 is filled in the trench to separate the gate conductive layers 15 from each other in between the pair of cell channel holes. By forming the trench and filling the trench with the insulation layer 19, the gate conductive layers are divided into conductive layers 15A formed about a first channel hole and conductive layers 15B formed about a second channel hole.

After the trench process is performed, the cell channel sacrificial layer 16 and the pipe channel sacrificial layer 13 are removed. The cell channel sacrificial layer 16 and the pipe channel sacrificial layer 13 are formed of the same material, for example, a nitride layer. Thus, a wet etch process, using, for example, phosphoric acid, is employed to remove the cell channel sacrificial layer 16 and the pipe channel sacrificial layer 13.

However, in the wet etch process using the phosphoric acid, the phosphoric acid removes the cell channel sacrificial layer 16 and the pipe channel sacrificial layer 13, and also may have an adverse influence on the other layers of the non-volatile memory device structure. More specifically, referring to FIG. 1B, portions of a pipe gate conductive layer 12A, interlayer dielectric layers 14A and 14B, and gate conductive layers 15A and 15B are also removed. This adverse influence on the structure is because a chemical reaction is sequentially performed from the top to the bottom of the sacrificial layer, the wet etch process is performed for a long time, and specifically, the nitride layer and the oxide layer have low etching selectivity.

For this reason, when the sacrificial layer is formed and then removed according to the conventional art, the interlayer dielectric layers 14A and 14B may be removed more than the gate conductive layers 15A and 15B, as shown by the stepped portion T, causing the channel hole to have a saw tooth shape.

When a charge blocking layer, a charge trap layer and a tunnel insulation layer are formed in the channel hole with the saw tooth shape to form memory cells, since interference occurs between adjacent gate electrode conductive layers, a memory device may not operate. As a result, a non-volatile memory device may not be reliable.

### SUMMARY

An embodiment of the present invention is directed to a method for fabricating a non-volatile memory device with a three-dimensional structure, which is capable of reducing a sacrificial layer removal time, and improving device properties by substantially preventing the damage of gate electrodes and an insulation layer between the gate electrodes, which may occur in a sacrificial layer removal process.

In accordance with an embodiment of the present invention, a method for fabricating a non-volatile memory device with a three-dimensional structure including: forming a pipe gate conductive layer on a substrate; forming a pipe channel hole in the pipe gate conductive layer; burying a first sacrificial layer in the pipe channel hole; stacking interlayer dielectric layers and gate conductive layers on the pipe gate conductive layer including the first sacrificial layer; forming a pair of cell channel holes in the interlayer dielectric layers and the gate conductive layers; forming a second sacrificial layer on a resultant structure including the pair of cell channel holes; and forming a third sacrificial layer with etching selectivity relative to the second sacrificial layer on the second sacrificial layer and filling the cell channel holes with the third sacrificial layer.

### BRIEF DESCRIPTION OF THE DRAWINGS

FIGS. 1A and 1B are cross-sectional views illustrating a process for forming a sacrificial layer in channel holes of a non-volatile memory device and a process removing the sacrificial layer.

FIGS. 2A to 2E are cross-sectional views illustrating a method for filling a sacrificial layer in channel holes of a non-volatile memory device in accordance with an embodiment of the present invention.

FIGS. 3A to 3C are cross-sectional views illustrating a method for removing a sacrificial layer buried in channel holes of a non-volatile memory device in accordance with an embodiment of the present invention.

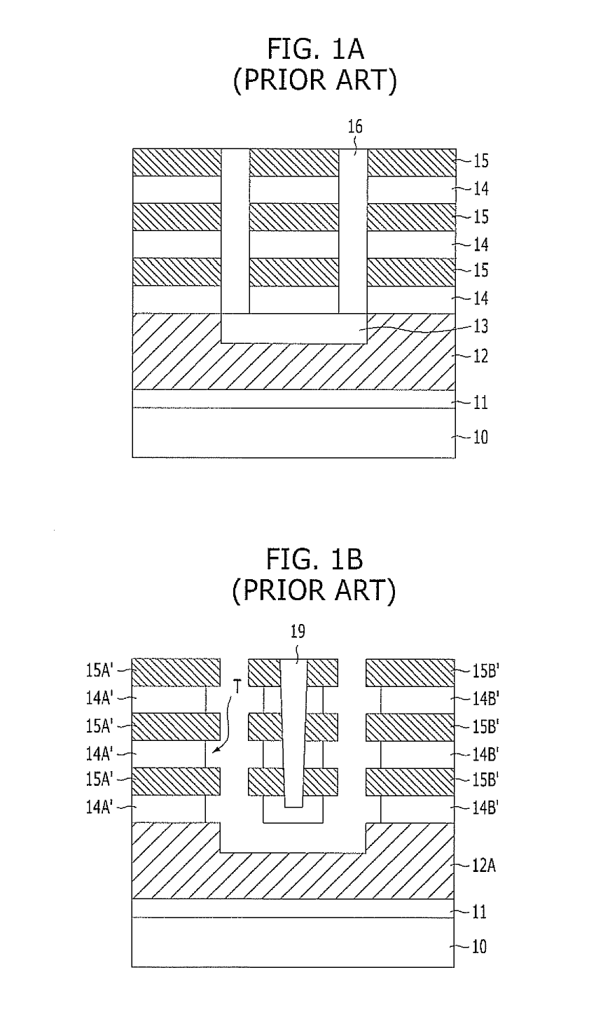

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

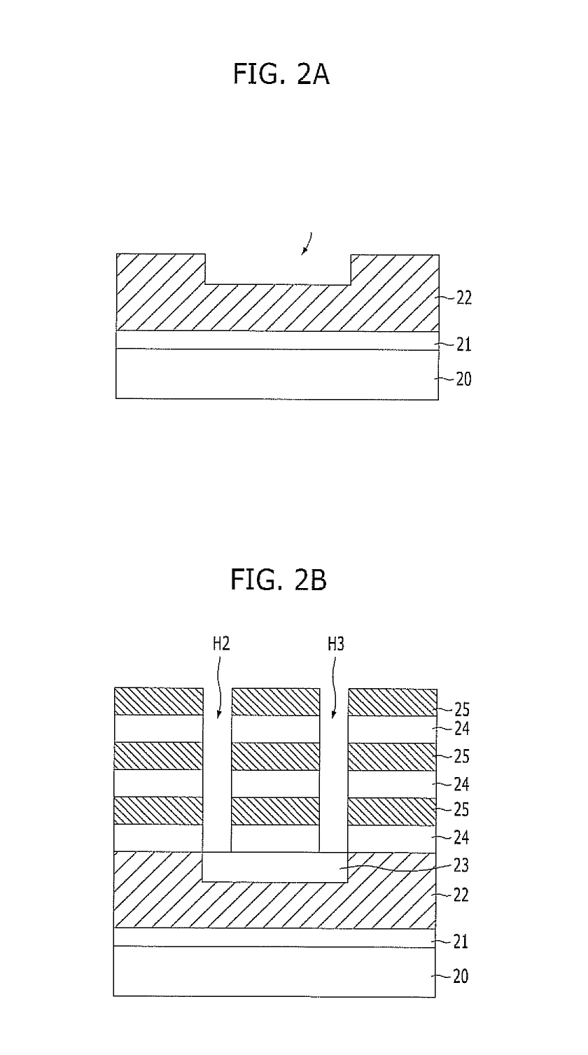

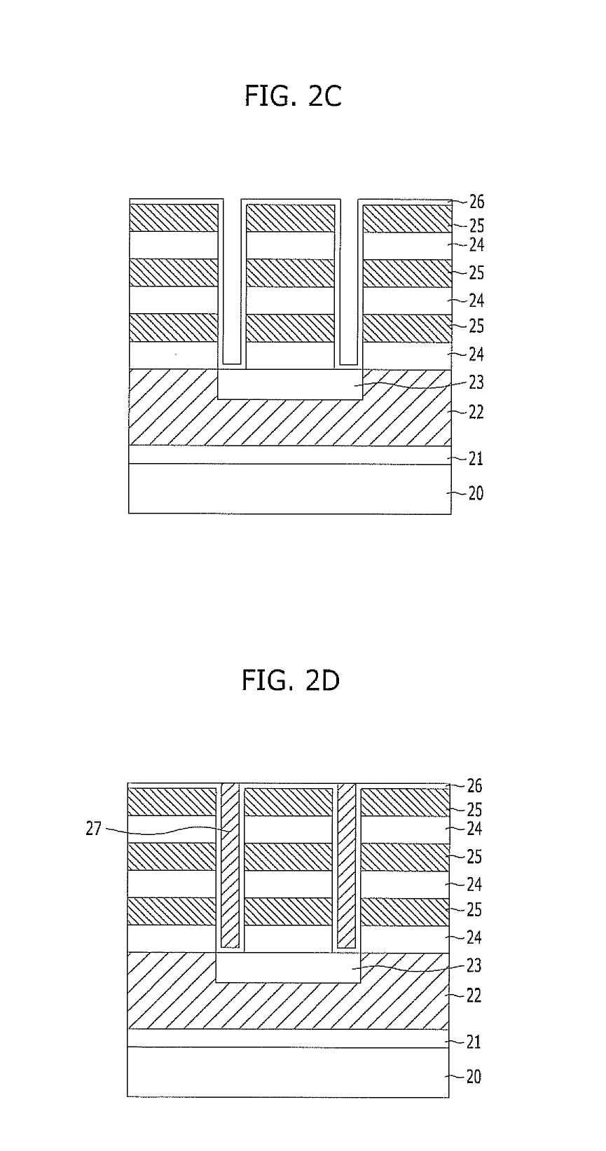

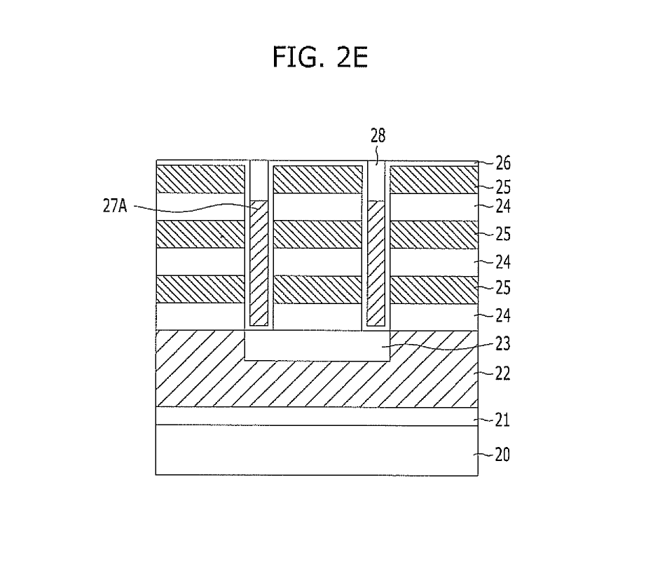

FIGS. 2A to 2E are cross-sectional views illustrating a method for filling a sacrificial layer in channel holes of a non-volatile memory device with a three-dimensional structure in accordance with an embodiment of the present invention.

Referring to FIG. 2A, an insulation layer 21 is formed on a substrate 20. The insulation layer 21 serves as an isolation layer to isolate the substrate from the structure formed above the substrate. The insulation layer 21 may include an oxide layer.

A pipe gate conductive layer 22 is formed on the insulation layer 21. The pipe gate conductive layer 22 may include a polysilicon layer.

The pipe gate conductive layer 22 is partially etched to form a pipe channel hole H1. The pipe channel hole H1 is a space where a pipe channel is to be formed in a subsequent process. The pipe channel connects a pair of cell channels formed above the pipe gate conductive layer 22.

In the above described process, the insulation layer 21 is formed on the substrate 20, the pipe gate conductive layer 22 is formed, and a part of the pipe gate conductive layer 22 is etched to form the pipe channel hole H1 in order to form a pipe gate. However, a part of the substrate 20 may be etched to form the pipe channel hole H1, so that the pipe gate may be formed.

Referring to FIG. 2B, a first sacrificial layer 23 is filled in the pipe channel hole H1. The first sacrificial layer 23 protects the pipe channel hole H1 in a subsequent process and may include a nitride layer.

Insulation layers 24 and memory cell gate conductive layers 25 are alternately stacked on the pipe gate conductive layer 22 and the first sacrificial layer 23. The insulation layers 24 isolate the gate conductive layers 25 from each other and may include an oxide layer. The gate conductive layers 25 serve as a gate electrode of a memory cell and may include a polysilicon layer.

The insulation layers 24 and the memory cell gate conductive layers 25 are etched to form a pair of cell channel holes H2 and H3 that expose the first sacrificial layer 23. A charge blocking layer, a charge trap layer/a charge storage layer, and a tunnel insulation layer are sequentially formed on sidewalls of the cell channel holes H2 and H3. A channel material is also filled in the cell channel holes H2 and H3.

Referring to FIG. 2C, a second sacrificial layer 26 is formed in the form of a liner along a side of the cell channel holes H2 and H3, the bottom of the cell channel holes H1 and H2, and on the uppermost memory cell gate conductive layer 25. The second sacrificial layer 26 may include a nitride layer or a silicon oxynitride layer.

The second sacrificial layer 26 protects the insulation layers 24 and the gate conductive layers 25 in a subsequent process, and is provided in the form of a liner in order to minimize the damage to the insulation layers 24 and the gate conductive layers 25 in a subsequent process to remove the second sacrificial layer 26.

Referring to FIG. 2D, a third sacrificial layer 27 is formed in the cell channel holes including the second sacrificial layer 26. The third sacrificial layer 27 has a high etching rate and an etching selectivity relative to the second sacrificial layer 26.

The third sacrificial layer 27 may be formed of a spin-on dielectric (SOD) layer. Since the SOD layer has excellent filling characteristics and high etching selectivity relative to the nitride layer included in the second sacrificial layer 26, the SOD layer can be quickly removed.

If the third sacrificial layer 27 uses a material including SOD, since the SOD layer is a flexible insulation layer, an annealing process for curing the layer may be further performed.

Referring to FIG. 2E, a process for forming a fourth sacrificial layer 28 serving as a capping sacrificial layer on the third sacrificial layer 27 may be further performed. To form the fourth sacrificial layer 28, an upper portion of the third sacrificial layer 27 is recessed and removed by a designated thickness. The fourth sacrificial layer 28, which has an etching selectivity relative to a third sacrificial layer 27A, is filled in a space obtained by recessing the third sacrificial layer 27. The fourth sacrificial layer 28 may include a material substantially similar as that of the second sacrificial layer 26. The fourth sacrificial layer 28 may include a nitride layer. The fourth sacrificial layer 28 may serve as a capping sacrificial layer compensating for the flexibility of the third sacrificial layer 27A, and may serve as a barrier layer in a subsequent CMP process.

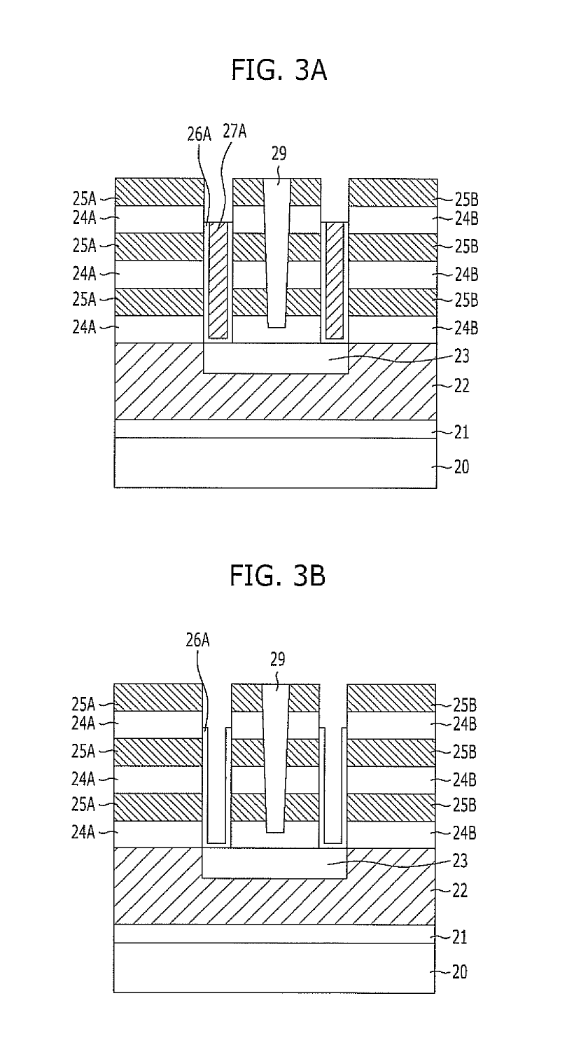

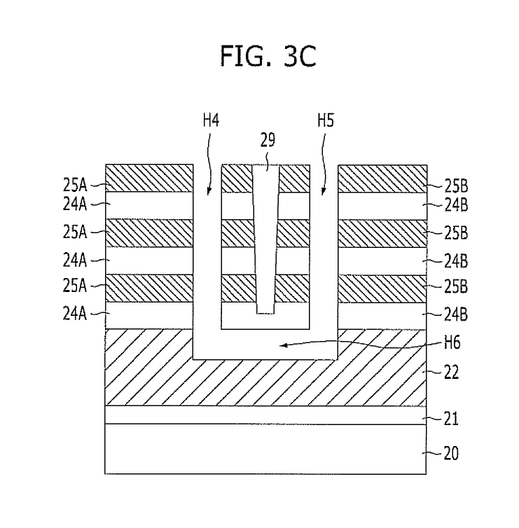

FIGS. 3A to 3C are cross-sectional views illustrating a method for removing a sacrificial layer buried in channel holes of a non-volatile memory device with a three-dimensional structure in accordance with the embodiment of the present invention. For illustration purposes, an upper structure and the like, which may be formed in a subsequent process, are not shown.

Referring to FIG. 3A, a trench process is performed for a structure where the first to fourth sacrificial layers 23, 26, 27A and 28 have been formed and buried. In the trench process, the gate conductive layers 25 formed between the cell channel holes are separated from each other by etching a trench between the cell channel holes. By forming the trench, word lines are separated from each other according to cell channels.

In the trench process, the gate conductive layers 24 and the interlayer dielectric layers 25 formed between a pair of cell channel holes are etched, thereby forming the trench. An insulation layer 29 is filled in the trench to separate the gate conductive layers 15 from each other in between the pair of cell channel holes. In this way, the gate conductive layer of a memory cell stack is divided into conductive layers 25A formed about a first channel hole and conductive layers 25B formed about a second channel hole.

The fourth sacrificial layer 28 is etched to expose the third sacrificial layer 27A. When the fourth sacrificial layer 28 is formed of a nitride layer in accordance with the embodiment of the present invention, an etch process using phosphoric acid may be used. For example, when the fourth sacrificial layer 28 is formed of a nitride layer, the nitride layer may be subject to a wet etch process using a phosphoric acid solution at the temperature of about 120° C. to about 180° C. The wet etch process is performed until the third sacrificial layer 27A is exposed. At this time, a part of the second sacrificial layer 26 formed above the third sacrificial layer 27A may also be removed. For example, when the second sacrificial layer 26 is formed of a nitride layer, the second sacrificial layer 26 formed above the third sacrificial layer 27A may also be removed in the wet etch process using the phosphoric acid solution. By removing a part of the second sacrificial layer 26 above the third sacrificial layer 27A, the remaining second sacrificial layer 26A is formed.

Referring to FIG. 3B, the exposed third sacrificial layer 27A is removed. Since the third sacrificial layer 27A has high etching selectivity relative to the second sacrificial layer 26A, the third sacrificial layer 27A can be removed selectively without removing the second sacrificial layer 26A. For example, when the third sacrificial layer 27A is formed of SOD, the SOD can be quickly removed by performing a wet etch process using one solution of BOE and HF.

Referring to FIG. 3C, the second sacrificial layer 26A is etched and removed. For example, when the second sacrificial layer 26A is formed of a nitride layer, the second sacrificial layer 26A can be removed by performing a wet etch process using phosphoric acid at the temperature of about 120° C. to about 180° C. In accordance with the embodiment of the present invention, the second sacrificial layer 26A is provided in the form of a liner with a designated thickness. Because the second sacrificial layer 26A is formed as a liner with a designated thickness, the second sacrificial layer 26A can be removed quickly. In this way, it is possible to minimize the damage of inner walls of the channel holes H4 and H5. In accordance with the embodiment, when the first sacrificial layer 23 is formed of a nitride layer, the first sacrificial layer 23 may be partially removed in the etch process to remove the second sacrificial layer 26A.

The first sacrificial layer 23 that remains after the etch process to remove the second sacrificial layer 26A is etched and removed so that a pipe channel hole H6 is formed. In this way, the pair of channel holes H4 and H5 are connected to the pipe channel hole H6, so that a pipe line channel hole can be formed.

A charge blocking layer, a charge trap layer/a charge storage layer, and a tunnel insulation layer (not illustrated) are sequentially formed on sidewalls of the pipe line channel hole and then a channel layer (not illustrated) is filled. Or, the charge blocking layer, the charge trap layer/the charge storage layer, the tunnel insulation layer, and a channel layer (not illustrated) are sequentially formed on the sidewalls of the pipe line channel hole and then the pipe line channel hole is filled with an insulation layer, so that a plurality of memory cells with a vertical channel can be formed. A non-volatile memory device is fabricated through a subsequent interconnection process and the like.

As described above, when the sacrificial layers are formed in accordance with the embodiment of the present invention, a process time for removing the sacrificial layers may be reduced. Consequently, the amount of damage to the memory cell gate conductive layer and the insulation layer may be minimized, thereby fabricating a non-volatile memory device with high reliability.

In the method for forming channel holes of a non-volatile memory device with a three-dimensional structure in accordance with the embodiment of the present invention, a sacrificial layer may be quickly removed. Also, by removing the sacrificial layers of a non-volatile memory device with a three-dimensional structure in accordance with the embodiment of the present invention, device properties may improve by preventing the damage to gate electrodes and an insulation layer formed between the gate electrodes.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a non-volatile memory device with a three-dimensional structure, comprising:
forming a pipe gate conductive layer on a substrate;
etching the pipe gate conductive layer to form a pipe channel hole;
forming a first sacrificial layer buried in the pipe channel hole;
alternatively stacking interlayer dielectric layers and gate conductive layers on the pipe gate conductive layer including the first sacrificial layer;
etching the interlayer dielectric layers and the gate conductive layers to form a pair of cell channel holes;
forming a second sacrificial layer on a structure including the pair of cell channel holes; and
forming a third sacrificial layer with etching selectivity relative to the second sacrificial layer on the second sacrificial layer and filling the cell channel holes with the third sacrificial layer.

2. The method of claim 1, further, after the forming of the third sacrificial layer, comprising:
recessing an upper portion of the third sacrificial layer by a thickness; and
forming a fourth sacrificial layer with etching selectivity relative to the third sacrificial layer on the recessed third sacrificial layer and filling the cell channel holes.

3. The method of claim 1, further comprising:
selectively removing the third sacrificial layer; and
removing the second sacrificial layer and the first sacrificial layer to open the cell channel holes and the pipe channel hole.

4. The method of claim 2, further comprising:
removing the fourth sacrificial layer;
selectively removing the third sacrificial layer; and
removing the second sacrificial layer and the first sacrificial layer to open the cell channel holes and the pipe channel hole.

5. The method of claim 2, wherein the second sacrificial layer is formed of a material which is substantially the same as a material of the fourth sacrificial layer.

6. The method of claim 1, wherein the first sacrificial layer is formed of a material which is substantially the same as to a material of the second sacrificial layer.

7. The method of claim 1, wherein the third sacrificial layer is formed of an oxide layer.

8. The method of claim 1, wherein the first sacrificial layer and the second sacrificial layer are formed of a nitride layer.

9. The method of claim 2, wherein the fourth sacrificial layer is formed of a nitride layer.

10. The method of claim 1, further, after the filing of the third sacrificial layer, comprising:
performing an annealing process.

11. The method of claim 3, wherein the third sacrificial layer is selectively removed using BOE or HF.

12. The method of claim 3, wherein the first sacrificial layer and the second sacrificial layer are removed using a phosphoric acid solution at a temperature of about 120° C. to about 180° C.

13. The method of claim 4, wherein the fourth sacrificial layer is removed using a phosphoric acid solution at a temperature of about 120° C. to about 180° C.

14. The method of claim 1, wherein the second sacrificial layer is formed in the form of a liner along a side of the pair of cell channel holes.

15. The method of claim 1, wherein the third sacrificial layer is formed of a spin-on dielectric layer.
